(19) United States
(12) Patent Application Publication
(10) Pub. No.: US 2008/0116943 A1
(43) Pub. Date: May 22, 2008

(54) True-differential DVI/HDMI line driver

(76) Inventor: Rajendran Nair, Gilbert, AZ (US)

Correspondence Address: Rajendran Nair;ComLSI Inc., 3838 E Encinas Ave, Gilbert, AZ, 85234, US

(21) Appl. No.: 11/633,879

(22) Filed: Dec. 5, 2006

Related U.S. Application Data
(63) Continuation of application No. 11/601,514, filed on Nov. 20, 2006.

(51) Int. Cl. H03K 3/00

(52) U.S. Cl. 327/108

(57) ABSTRACT

A novel source-coupled differential driver circuit fully compatible with digital visual interface (DVI/HDMI) signaling specification is disclosed. Driven output signals are connected to the source terminals of driving switches in the invention circuit, minimizing the detrimental impact of miller coupling capacitance between gate nodes and driven output nodes upon output slew-rate, enabling higher frequencies of operation. Undriven output wires are connected to source-termination impedances, providing a matched return current to the driven current signal, and reducing return path impedance substantially. Matched differential current drive from the source ensures true-differential signaling, eliminating shield current flow and improving signal integrity. Bit error rate (BER) is reduced and overall link performance is significantly enhanced due to improved slew rates, true-differential signaling and greater signal integrity, enabling long reach and high-speed, high-definition multi-media data transmission.

### RELATED DOCUMENTS

This application is a continuation of U.S. application Ser. No. 11/601514, the specification and claims of which are incorporated herein by reference.

### TECHNICAL FIELD OF THE INVENTION

Embodiments of the invention relate to electronic circuitry commonly employed to transmit multimedia data in binary signal form over lengths of interconnect to other electronic circuits, devices and systems. Such circuitry falls under the category of Data Communication circuits.

### BACKGROUND & PRIOR ART

Low Voltage Differential Signaling (LVDS) is ubiquitous in the art. The popularity of this signaling technique arose in part from the expectation of substantially reduced power consumption because of the low (˜350 mV) swing on the lines as well as the differential nature of the signals that enabled accurate recognition despite static or dynamic variations in ground or supply voltages between the transmitting and receiving systems. Low signal swing also permits faster signal transitions, enabling higher rates of data transmission. Additionally, the differential and low-swing nature of signals also minimizes electromagnetic interference (EMI) and emissions from the signaling interconnect. Hence LVDS became the signaling method of choice for point-to-point links such as high-speed links between peripheral components of a computing system (USB), networking interconnect infrastructure installed in buildings (Ethernet) etc. Another low-swing signaling link promoted by an industry working group (Digital Display Working Group) is the Digital Video Interface specification [DVI, reference 1]. This specification details a method for data communication between a digital video content device and a digital video display device; the specification is supported by a number of companies in the industry with compliant components. DVI 1.0 specifies the use of Transition Minimized Differential Signaling (TMDS) intended to reduce electromagnetic emissions from the data link by reducing the number of binary transitions. The voltage swing is also minimized to approximately 500 mV on each wire of the differential pair. A typical TMDS driver is shown in FIG. 1.

TMDS uses low-swing signals, but is not necessarily low-power since the terminating voltage employed, as defined in DVI 1.0, is 3.3 V. In order to produce a 500 mV swing across a 50 Ohm terminating resistor at the far end of the link, the minimum current required is 10 mA. TMDS is not truly differential in action, since current flow is only activated on one wire of the differential wire pair at any time. For example, with reference to FIG. 1, when switch S1 is activated, S2 is turned ‘off’, and a current corresponding to the current-source Is flows in terminating resistor R1. Due to strong coupling between the wires of the differential wire pair, a ‘return’ or complimentary current is induced in the wire connecting between switch S2 and terminating resistor R2 that charges the inactive complimentary wire up to AVCC. Since the voltage source feeding currents into the differential wires is at the far end of the link, and the driver drives at the near end with a current source to ground, the DC current loop is completed through the shield of the link cable. Additionally, there is signal current flow in the shield based upon coupling, or differences in coupling, of the differential pair wires to the cable shield. These are undesirable characteristics of DVI electrical and physical layers and TMDS that necessitate high quality and associated cost in video cable construction in order to maintain acceptable bit error rates.

Prior art TMDS CMOS drivers as illustrated in FIG. 1 have significant functional disadvantages that impact output signal integrity. Detrimental impact to output slew rate as well as to output signal integrity due to miller coupling capacitances of prior art line drivers is explained in application Ser. No. 11/601514 [reference 1]. Another important disadvantage is the single-ended action of the prior art line driver. As explained in the preceding paragraphs, TMDS drivers connect to signal lines in an open-drain manner, with signal termination at the far-end of the link, and the driver activates (drives current through) only one line at a time. Because any practical transmission line is associated with a return path, for the completion of the current loop, a return current flows in the companion line to the activated signal line. But the return current flow is non-ideal, and distributed between the companion line and an enclosing shield line based upon the coupling of the signal conductors to each other and the shield. At the far-end of the link, therefore, the two currents flowing in the termination resistors are not identical and opposite as desired, and this leads to substantial signal integrity concerns. As frequencies increase with corresponding increased losses in the transmission lines and signal wavelengths as well as bit cell durations decrease, return path non-idealities as well as impedance discontinuities further degrade the signal transmitted by prior art pseudo-differential line drivers. An improved driver circuit is therefore necessary.

### INVENTION SUMMARY

The invention improves upon prior art DVI line driver substantially through the incorporation of true-differential line current drive while maintaining compatibility with DVI/HDMI receiver circuits. Driven output wire is connected to a current source, while the complementary output wire is connected to a source-termination impedance, providing a matched return current to the driven current signal, and reducing return path impedance substantially. Matched differential current drive from the source ensures true-differential signaling, eliminating shield current flow and improving signal integrity. The circuitry uses source-coupled drive in addition, enhancing gain for the higher frequencies associated with symbol transitions substantially, increasing data eye opening and signal integrity, thereby reducing bit error rates for high frequencies of operation. A transmitter termination impedance implementation assists with minimizing reflections from impedance discontinuities in the return current pathway, further enhancing signal integrity. The line driver lends itself to transmitter emphasis, mitigating the effects of inter-symbol interference and extending the reach of advanced DVI/HDMI links by 2× or more without the use of repeaters.

### BRIEF DESCRIPTION OF THE FIGURES

FIG. 1 illustrates a typical prior art TMDS driver and termination circuit architecture.

FIG. 2 is an illustration of the invention SCDL true-differential driver circuit and termination.

FIG. 3 is an alternate embodiment of the invention employing a single source termination.

FIG. 4 is an alternate embodiment with programmable source termination.

FIG. 5 illustrates one possible embodiment of terminating impedances in the invention as a series combination of a resistance element with a reactance element.

FIG. 6 illustrates an embodiment of the invention using a cascode current source and one embodiment of transmit emphasis.

FIG. 7 is an embodiment with true-differential far-end termination.

### DETAILED DESCRIPTION

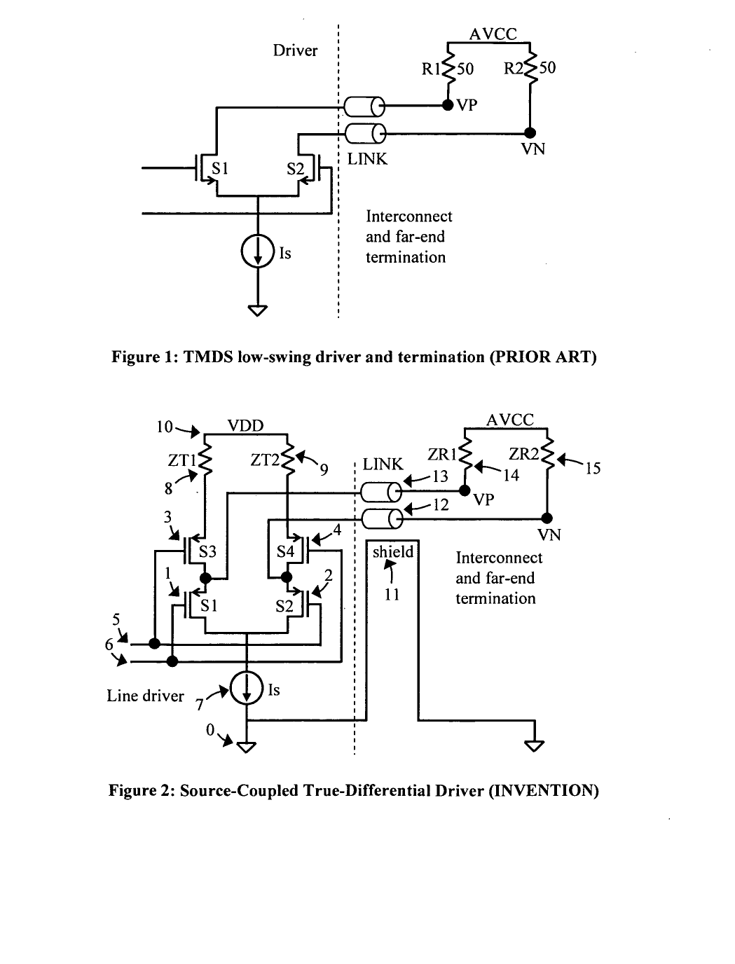

A prior art embodiment of a TMDS differential signaling output driver and termination architecture is illustrated in FIG. 1. In this driver implemented in CMOS technology, a tail current source connects through two NFET switch devices to output signal wires which are terminated at the far-end of the cable in a single-ended manner to a common reference power supply AVCC. When switch S1 turns ‘off’ and S2 turns ‘on’ driven by input signals to the gates of these devices, the current source current Iₛ is diverted to flow through the output signal wire connecting to far-end node VN and through terminating resistance R2, thereby pulling node VN lower by a voltage value corresponding to the product of the current and the terminating resistance. In typical embodiments of the prior art, the terminating resistors are 50 Ohms in value and the current source is 10 mA, resulting in a 500 mV drop in voltage. Simultaneously, since switch S1 turns ‘off’, no current flows through the output signal wire connecting to far-end node VP, and this signal wire charges up to the reference voltage AVCC. The close electromagnetic coupling between the two output wires (they are designed as a pair to present 100 Ohms characteristic impedance) ensures that the current flow activated in one signal wire induces an opposite current flow in the companion wire, thus ensuring a degree of differential current flow, diminishing radiated energy from the wires through cancellation of external fields.

An issue with the prior art driver as shown in the illustration in FIG. 1 is that the switch devices in the driver circuit are relatively large, and possess significant parasitic capacitances that impact output signal integrity. With reference to FIG. 1, the gate to drain capacitance of switch S2 conveys a portion of the activating signal that turns S2 ‘on’ to the drain node, thus yanking the drain node high by a fraction of the signal transition that activates switch S2. This is the ‘miller’ coupling capacitance effect, where the output signal feeds through to the input, or in this instance, the input signal feeds through to the output based upon the impedance presented by the output node. A second, equally significant problem in the prior art driver of FIG. 1 is that the signaling action is largely one-sided; the pull-down current source is connected only to one wire at a time. The other signal wire reflects the current flowing in the activated signal wire as a ‘return current’ because of the close coupling between the two differential signal wires. But the differential wire pair also couple to the shield, and the return current takes both pathways, leading to non-ideal differential signaling and diminished signal integrity.

Both these problems are effectively addressed by the invention as illustrated by the embodiment of FIG. 2. Each current-steering switch (S1 or S2) is associated with a termination path to the reference supply AVCC through another switch also connecting to the differential inputs that drive the current-steering switches. In FIG. 2, for example, switch S1 is associated with a companion switch S3, with the input signal to S3 being complementary (or the opposite) of the input signal to switch S1. Hence when the input to switch S1 goes low, turning the PFET switch ‘on’, the input to switch S3 goes high, turning it ‘off’. In this embodiment, these two state transitions couple through the parasitic miller capacitances and cancel each other out, thus eliminating the impact of input transitions upon output signal integrity. Additionally, when switch S1 turns off (and S2 turns on), switch S3 turns on, connecting a terminating impedance to the output wire disconnected from the pull-down current source and providing a charging current that is designed to match the pull-down current flowing through switch S2 and the output signal wire connected to the pull-down current source. This ensures that a source and sink current are supplied by the line driver to the output signal wires, rendering the driven signal truly differential.

With reference to the invention embodiment illustrated in FIG. 2, node 0 is ground, device 7 is the pull-down current source, transistors S1 and S2 (devices 1 and 2) are the differential current-steering transistors coupled at their source terminals to the output signal nodes of the line driver, switches S3 and S4 (devices 3 and 4) are a pair of controlled switch devices that alternately connect the output signal nodes through terminating impedances Zt1 and ZT2 (devices 8 and 9) to the local reference supply voltage VDD (node 10). Input nodes 5 and 6 provide the differential drive signal to the line driver. Component 11 is a shield conductor that lies adjacent to the differential output signal wires 12 and 13 and shorts the ground nodes of the transmitter and receiver systems. Devices 14 and 15 (ZR1 and ZR2) for far-end terminating impedances connecting the far end differential nodes of the link to a local stable voltage reference AVCC at the receiver.

The miller coupling capacitances across switches S1 and S2 in the invention embodiment illustrated in FIG. 2 assist in output signal development, since PFET devices require a negative voltage swing at their input in order to turn ON, and the output signal desired from the driver is also a negative voltage swing down from the far-end reference voltage AVCC. Similarly, a PFET switch is turned ‘off’ by the input to its gate node going high, while the output wire connecting to the switch also transitions high towards the reference voltage AVCC. This ‘in-phase’ relationship between drive and output signals ensures that the energy developed by pre-driver circuits driving signal inputs 5 and 6 is conveyed through the miller capacitances to assist in the output development, thereby improving the driver's overall energy efficiency per transition. This benefit of the invention has been explained in greater detail in the application that this application is a continuation of [reference 1]. In the invention contemplated by this application, the benefit of transfer of input driving signal energy to the output signals for improved slew rate and amplified bit-transition spectral components (high-frequency components) may be retained either by employing full transmission gates in place of switches S3 and S4, or by explicitly adding coupling capacitors from the driving input signal nodes to the driven output signal nodes, in parallel with the miller capacitances of switches S1 and S2.

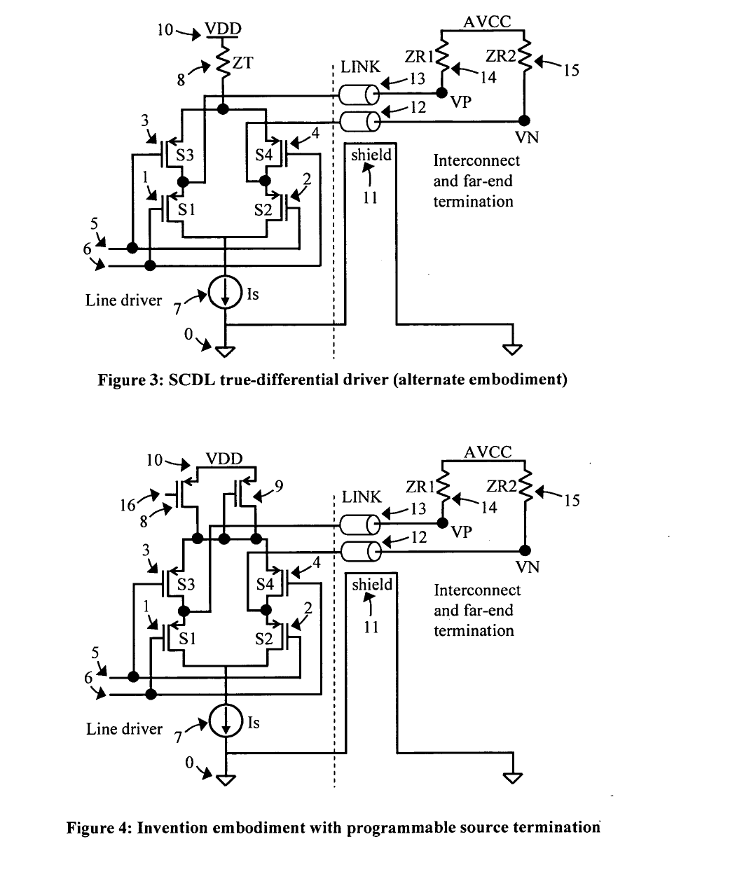

FIG. 3 illustrates an embodiment employing a single transmit impedance ZT that is connected to each non-driven output signal wire alternately. The use of a single transmit impedance improves matching of return-path impedances between the two wires. Nevertheless, the embodiment illustrated in FIG. 2 with separate matched transmit termination impedances is advantageous since these termination impedances can also serve as terminating impedances shared by a companion receiver in a transceiver implementation. In such a modification, the controlled switches S3 and S4 (of FIG. 2) may be controlled independently, allowing for a state where both are turned ‘on’ while S1 and S2 are turned ‘off’ simultaneously to emulate hard-wired termination impedances for the receiver circuit connecting to the external signal nodes.

FIG. 4 illustrates an embodiment with a programmable transmit termination impedance. Transistors 8 and 9 controlled by bias signal 16 form a linearized active load that can be adjusted based on characteristics of the transmission line pair connecting to the output signal nodes.

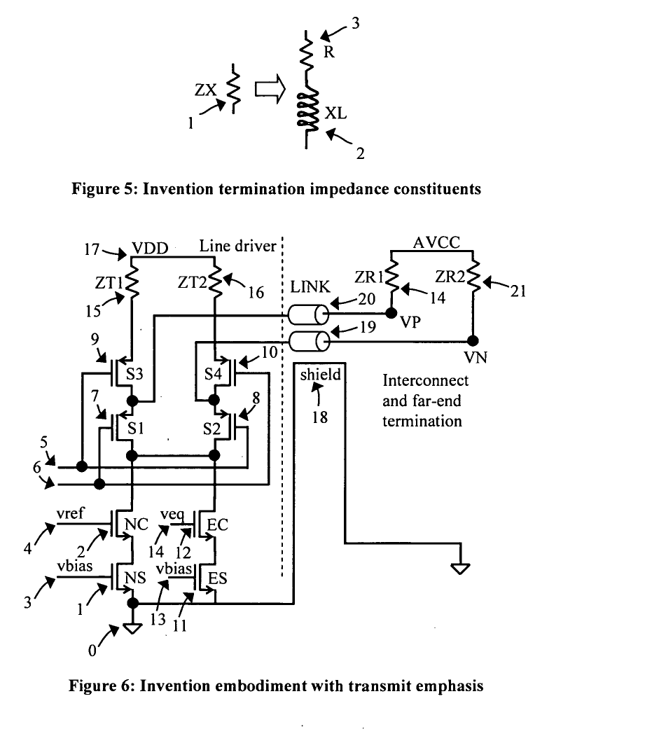

FIG. 5 illustrates passive equalization functionality integrated into the termination impedances of the invention. In one embodiment, a resistor of value matching the single-ended characteristic impedance of the link wire is employed in series with an inductor that presents reactive impedance to the high frequency spectral components of the data signals. Such a combination of a resistor and an inductor presents impedance that varies with respect to frequency, increasing with increasing frequency, thereby compensating to an extent for the frequency dependent attenuation inherent in practical signal wire pairs.

An alternate embodiment of the invention including transmitter emphasis is shown in FIG. 6. The DVI specification does not discuss this well-known technique that assists in compensating for inter-symbol interference (ISI), a common malady of lossy interconnect links transmitting binary signals at a high rate. In actuality, overshoot and undershoot limits in the DVI specification severely restrict the use of transmit emphasis. Nevertheless, techniques such as pre-emphasis and de-emphasis that enhance the high-frequency spectral content of transmitted data can assist in improving signal integrity and the reach of DVI cable links. The invention transmitter circuit architecture lends itself nicely to the inclusion of transmit emphasis. With reference to FIG. 6, devices 11 and 12 form an additional current source pathway controlled by signals 13 and 14, or VBIAS and VEQ respectively. In one embodiment, signal 13 is the same as signal 3, providing a bias voltage value to the current source devices NS and ES, which are also designed to conduct exactly the same current value. Signal 14, or VEQ, is controlled according to the emphasis technique implemented. In a de-emphasis implementation, signal VEQ is switched between ground and VREF depending upon the symbol sequence. When a data symbol transition (from high to low or vice-versa) occurs, both current source pathways are made active, resulting in twice the current flow and correspondingly, twice the voltage swing at the output. If the succeeding symbol is the same as its predecessor, the equalizing current pathway is disabled through signal 14 or VEQ pulled down to ground. In this manner, symbol sequences of two or more of the same value employ one-half the maximum pull-down current, while data bits with symbol transitions employ the full pull-down current. Therefore the output signal amplitude for data bits with symbol transitions is twice that for those bits that do not have a transition, as desired in simple, 1-bit de-emphasis signal conditioning.

It will be evident to one skilled in the art that this transmit emphasis technique may be implemented to a finer resolution (multiple bits) by employing additional equalizing current source branches, and by designing their values and activation control so as to provide the desired equalization function. It will also be evident that the pre-emphasis equalization technique may be similarly implemented in alternate invention embodiments.

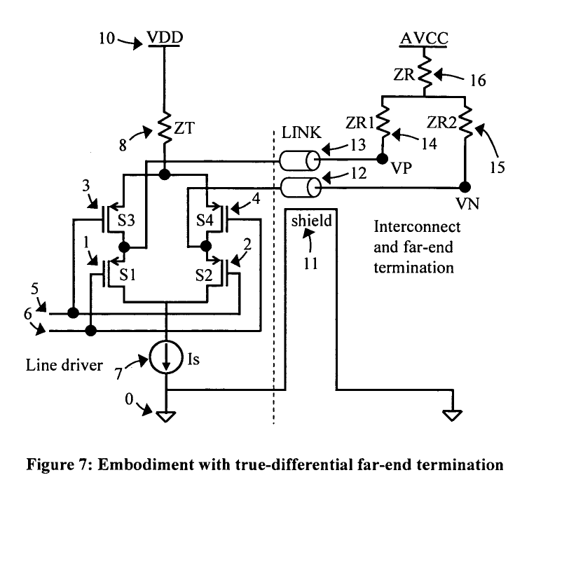

FIG. 7 illustrates an embodiment approaching true-differential far-end termination. With reference to this figure, one skilled in the art can see that by making the line driver power supply VDD higher than the far-end receiver reference AVCC, or instead, by lowering AVCC with respect to VDD, the embodiment achieves a differential voltage swing across termination impedances ZR1 and ZR2 with AVCC being the ‘common-mode’ or cross-over reference voltage level. Given the nature of DVI/HDMI receiver circuits, operating with a high common-mode voltage near 3.3 V, it is feasible to lower AVCC substantially without having to change the circuit architecture of the receiver.

Although specific embodiments are illustrated and described herein, any circuit arrangement configured to achieve the same purposes and advantages may be substituted in place of the specific embodiments disclosed. This disclosure is intended to cover any and all adaptations or variations of the embodiments of the invention provided herein. All the descriptions provided in the specification have been made in an illustrative sense and should in no manner be interpreted in any restrictive sense. The scope, of various embodiments of the invention whether described or not, includes any other applications in which the structures, concepts and methods of the invention may be applied. The scope of the various embodiments of the invention should therefore be determined with reference to the appended claims, along with the full range of equivalents to which such claims are entitled. Similarly, the abstract of this disclosure, provided in compliance with 37 CFR §1.72(b), is submitted with the understanding that it will not be interpreted to be limiting the scope or meaning of the claims made herein. While various concepts and methods of the invention are grouped together into a single ‘best-mode’ implementation in the detailed description, it should be appreciated that inventive subject matter lies in less than all features of any disclosed embodiment, and as the claims incorporated herein indicate, each claim is to viewed as standing on it's own as a preferred embodiment of the invention.

### REFERENCE

1. Digital Display Working Group “DVI 1.0 Specification”, http:/www.ddwg.org/lib/dvi_{—}10.pdf
2. Telecommunications Industries Association/Electronics Industries Association signaling standard TIA 644-A, “Electrical characteristics of low voltage differential signaling . . . ”, http:ftp.tiaonline.org/tr-30/tr302/Public/2000%20Contributions/20005017.pdf

### PRIOR ART

1. Rajendran Nair, “Source-Coupled Differential Low Swing Driver Circuits”, U.S. Utility patent application Ser. No. 11/601514
2. Russel A. Martin, U.S. Pat. No. 6.307.543, Bi-directional data transfer using two pair of differential lines as a single additional differential pair
3. Roger Dale Emeigh et. al, U.S. Pat. No. 5.767.698, High speed differential output driver with common reference
4. Lin-Kai Bu, U.S. Pat. No. 6.873.660, High bandwidth low power differential transmitter
5. Anthony Yap Wong, U.S. Pat. No. 6.288.581, Low-voltage differential-signaling output buffer with pre-emphasis

What is claimed is:

1. A line driver for differential signal output, comprising
a current source connecting to a first stable voltage source;
a pair of current-steering metal-oxide-semiconductor field-effect transistors with their drain terminals connecting together and to the current source, and source terminals connecting to the differential output signal nodes of the driver, receiving at their gate inputs a true and complementary differential signal pair;
and a pair of controlled switch devices, each connecting to an output signal node and a current-steering transistor's source node at one conducting terminal, and at its other conducting terminal through a transmitter termination impedance to a second stable voltage source, receiving at their control inputs the true and complementary differential signal pair.

2. The apparatus of claim 1, with the differential outputs connecting through a differential signal wire pair to receiver termination impedances attached to a second stable voltage source, employed to generate complementary voltage swings across the receiver termination impedances.

3. The apparatus of claim 2 where the second stable voltage reference and receiver termination impedances are part of a receiver system not containing the line driver apparatus.

4. The apparatus of claim 3 where the terminating impedances are resistors matched to the characteristic impedance of the signal pathways in series with inductors, such that the terminating impedance presented increases with frequency.

5. The apparatus of claim 3, with p-type field-effect transistors employed as current-steering devices and p-type field-effect transistors employed as controlled switch devices.

6. The apparatus of claim 3, with p-type field-effect transistors employed as current-steering devices and transmission gate devices comprised of both p-type and n-type field effect transistors employed as controlled switch devices.

7. The apparatus of claim 5 employed in DVI/HDMI compatible systems and data communication links.

8. The apparatus of claim 7 where a shield conductor connecting to ground at both the line driver and the receiver systems accompanies in close proximity the differential signal wire pairs forming the communication link.

9. The apparatus of claim 8 where the communication link lengths substantially exceed DVI/HDMI specifications.

10. The apparatus of claim 1 where the current source comprises of a controlled transistor with a bias signal provided to its control node and a cascode transistor in series with the controlled transistor with a reference signal provided to its control node.

11. The apparatus of claim 10, with one or more additional cascoded current sources connecting between the current-steering transistors and the first stable voltage source, employed for symbol-dependent drive current modulation.

12. The apparatus of claim 11 employed for de-emphasis signal equalization.

13. The apparatus of claim 11 employed for pre-emphasis signal equalization.

14. A method for differential output signal generation, comprising:
steering a current through a field-effect transistor into a driven output signal wire such that the driving signal steering the current is in phase with the output voltage developed;
while simultaneously activating a switch connecting the complementary output signal wire through terminating impedances or current limiting circuits to a termination reference voltage so as to provide a matched current flow in the complementary output signal wire of a polarity opposite to that of the steered current flow in the driven output signal wire.

15. The method of claim 14 where current flows through a p-type metal-oxide-semiconductor field-effect transistor from an output node to ground, and a p-type MOSFET controlled switch connects the complementary output node through a terminating impedance to a positive reference power supply.

16. The method of claim 14, where the steered current magnitude for a transmitted data bit is dependent upon one or more preceding data bits transmitted.

17. The method of claim 14, where the rate of change of voltage on the driven output node is amplified by coupling a substantial portion of the energy of both the driving signal effecting the current steering and the activating signal input to the controlled switch.

18. Electronic systems comprised of various integrated and discrete electronic circuits and devices that employ the apparatus of claim 1 in any embodiment.

19. Integrated or discrete output driver circuits that employ the method of claim 14 in any of its implementations.
